(19) United States
(12) Patent Application Publication
(10) Pub. No.: US 2026/0110743 A1
(43) Pub. Date: Apr. 23, 2026

(54) METHOD AND DEVICE FOR PREDICTING CURRENT-VOLTAGE CHARACTERISTICS

(71) Applicant: Nisshinbo Holdings Inc., Tokyo (JP)

(72) Inventors: Takuya MAIE, Chiba-shi (JP); Seiya NORO, Chiba-shi (JP); Yuji KUBOTA, Chiba-shi (JP)

(73) Assignee: Nisshinbo Holdings Inc., Tokyo (JP)

(21) Appl. No.: 19/365,768

(22) Filed: Oct. 22, 2025

(30) Foreign Application Priority Data
Oct. 23, 2024 (JP) 2024-186514

(51) Int. Cl. G01R 31/367; G01R 31/378; G01R 31/385; G01R 31/389

(52) U.S. Cl. CPC G01R 31/367; G01R 31/378; G01R 31/385; G01R 31/389

(57) ABSTRACT

A method of predicting current-voltage characteristics of the present invention includes a first step of performing an RRDE measurement to obtain an actual measured value of the electrode current, a second step of solving Equation (1) below regarding a concentration distribution of oxygen molecules and hydrogen peroxide molecules on an electrode surface of a fuel cell and obtaining a calculated value the electrode current, a third step of performing mathematical optimization of a calculated value such that a difference between the calculated value and the actual measured values is reduced, and a fourth step of substituting the calculated value after the mathematical optimization into a Butler-Volmer equation to obtain an activation voltage under a condition that the electrode reaction is in equilibrium and obtaining the current-voltage characteristics, in which the calculated value obtained in the second step is the sum of electrode currents for each active site,

$$\begin{matrix}[ Equation 1 ] & \\ \frac{\partial }{\partial t} C = D \frac{{\partial }^{2}}{\partial {x}^{2}} C + KC = O & ( 1 )\end{matrix}$$

(C is a concentration distribution, D is the diffusion coefficient, and K is the reaction rate constant).

### BACKGROUND OF THE INVENTION

### Field of the Invention

The present invention relates to a method of predicting current-voltage characteristics and a current-voltage characteristic prediction device.

Priority is claimed on Japanese Patent Application No. 2024-186514, filed Oct. 23, 2024, the content of which is incorporated herein by reference.

### DESCRIPTION OF RELATED ART

A fuel cell attracts attention as a power generation device with a low environmental load and a high-power generation efficiency. The fuel cell has a function of chemically reacting hydrogen and oxygen to directly convert chemical energy into electric energy. The fuel cell is mainly composed of an electrolyte membrane, a catalyst layer, and a gas diffusion layer, and particularly, the performance of a catalyst included in the catalyst layer has a large effect on current-voltage characteristics of the fuel cell. In the fuel cell in the related art, a platinum-supported catalyst (Pt/C) is used (Japanese Unexamined Patent Application, First Publication No. 2017-045549 and the like), but from the viewpoint of cost and resources, it is required to reduce the amount of platinum in a catalyst layer and to remove platinum from the catalyst layer.

There are mainly two types of measurements for evaluating characteristics of a fuel cell. One is a measurement (IV measurement) performed by actually supplying hydrogen and oxygen by assembling a membrane-electrode assembly (MEA). This measurement is a measurement with a configuration close to a fuel cell, but a measurement procedure is complicated and a large amount of samples is required. The other is a measurement (RRDE measurement) using a rotating ring-disk electrode in an oxygen-saturated solution. In the measurement using the rotating ring-disk electrode, the measurement procedure is simple and can be performed with a small number of samples, but it is difficult to perform with high accuracy.

### CITATION LIST

### Patent Document

Patent Document 1: Japanese Unexamined Patent Application, First Publication No. 2017-045549

### SUMMARY OF THE INVENTION

The present invention is made in view of the above circumstances, and an object of the present invention is to provide a method of predicting current-voltage characteristics and a current-voltage characteristic prediction device, which enable easy prediction of current-voltage characteristics of a fuel cell including a catalyst composed of any material with high accuracy.

In order to solve the above-described problem, the present invention employs following means.
[1] A method of predicting current-voltage characteristics according to an aspect of the present invention is a method of predicting current-voltage characteristics of a fuel cell, and includes a first step of performing an RRDE measurement that simulates the fuel cell to obtain actual measured values of the electrode current density of a disk electrode and the electrode current of a ring electrode which are generated by an electrode reaction, a second step of solving Equation (1) below regarding a concentration distribution of oxygen molecules and hydrogen peroxide molecules on an electrode surface in the RRDE measurement to obtain a calculated value of the electrode current density and the electrode current from the obtained concentration distribution, a third step of performing mathematical optimization of the calculated value such that a difference between the actual measured values and the calculated value is equal to or less than a specified value, and a fourth step of substituting the calculated value after the mathematical optimization into a Butler-Volmer equation to obtain an activation voltage under a condition that the electrode reaction is in equilibrium, and obtaining the current-voltage characteristics, in which the calculated value obtained in the second step is the sum of the electrode current density and the electrode current, which correspond to the energy change for each active site.

$$\begin{matrix}Equation 1 & \\ \frac{\partial }{\partial t} C = D \frac{{\partial }^{2}}{\partial {x}^{2}} C + KC = O & ( 1 )\end{matrix}$$

C represents a concentration distribution of the oxygen molecules and the hydrogen peroxide molecules in a catalyst layer, D represents the diffusion coefficient of the oxygen molecules and the hydrogen peroxide molecules, and K represents the reaction rate constant of the catalyst layer formed on the electrode surface.
[2] In the method of predicting current-voltage characteristics described in [1] above, the concentration distribution C, the diffusion coefficient D, and the reaction rate constant K are each represented by Equation (2) to Equation (4) below.

$$Equation 2$$

$$C = ( \begin{matrix}{C}_{{O}_{2}} \\ {C}_{{H}_{2} {O}_{2}}\end{matrix} ) \qquad ( 2 )$$

$$Equation 3$$

$$D = ( \begin{matrix}{D}_{{O}_{2}} & 0 \\ 0 & {D}_{{H}_{2} {O}_{2}}\end{matrix} ) \qquad ( 3 )$$

$$Equation 4$$

$$K = ( \begin{matrix}- {K}_{2} & {K}_{4} \\ {K}_{2} & - {K}_{4} - {K}_{3}\end{matrix} ) \qquad ( 4 )$$

C_{O2} and C_{H2O2} represent concentration distributions of the oxygen molecules and the hydrogen peroxide molecules in the catalyst layer. D_{O2} and D_{H2O2} represent diffusion coefficients of oxygen molecules and hydrogen peroxide molecules. K₂, K₃, and K₄ represent reaction rate constants of the catalyst layers in the synthesis reaction of the hydrogen peroxide molecules, the synthesis reaction of water molecules, and the decomposition reaction of the hydrogen peroxide molecules.
[3] In the prediction method of current-voltage characteristics described in [1] or [2] above, it is preferable that the energy change for each active site is an energy change for two or more active sites having different activities in the catalyst layer.
[4] In the method of predicting current-voltage characteristics described in any one of [1] to [3] above, it is preferable that, in the fourth step, the Butler-Volmer equation is multiplied by the ratio of the catalyst amount to the catalyst density.
[5] In the method of predicting current-voltage characteristics described in any one of [1] to [4] above, it is preferable that the mathematical optimization in the third step is performed such that an error index ΔS represented by Equation (5) below is −1.1 or less in the electrode current density of the disk electrode and is in a range of −0.9 or less in the electrode current of the ring electrode.

$$Equation 5$$

$$Δ S = {log}_{10} \frac{{\sum }_{E ∈ {E}_{met}} \vert {I}_{M} - {I}_{C} \vert}{{\sum }_{E ∈ {E}_{met}} \vert {I}_{M} \vert} \qquad ( 5 )$$

I_{M} and I_{C} are the actual measured value and the calculated value of the electrode current density of the disk electrode and the electrode current of the ring electrode in the RRDE measurement. The sum is performed with respect to a potential condition Eₘₑₜ in the actually measured potential.
[6] In the method of predicting current-voltage characteristics described in any one of [1] to [5] above, it is preferable that, in the fourth step, the decrease due to a concentration overvoltage and the resistance overvoltage is subtracted from the activation voltage of the fuel cell.
[7] In the method of predicting current-voltage characteristics described in any one of [1] to [6] above, a first database may be generated for a relationship between the catalyst amount and the concentration overvoltage, and the concentration overvoltage may be predicted with reference to the first database.
[8] In the prediction method of current-voltage characteristics described in any one of [1] to [7] above, a second database may be generated for a relationship between the ratio of the ionomer amount to the catalyst amount in the catalyst layer and the resistance overvoltage, and the resistance overvoltage may be predicted with reference to the second database.
[9] A current-voltage characteristic prediction device according to an aspect of the present invention is a current-voltage characteristic prediction device that is used for the method of predicting current-voltage characteristics described in any one of [1] to [8] above, and includes an input device configured to input the actual measured values of the electrode current density of the disk electrode and the electrode current of the ring electrode generated by the electrode reaction, by using the RRDE measurement, a first calculation device configured to solve the Equation (1) to obtain the calculated value of the electrode current density and the electrode current from the obtained concentration distribution, a second calculation device configured to perform the mathematical optimization of the calculated value such that a difference between the actual measured values and the calculated value is a specified value or less, and a third calculation device configured to substitute the calculated values after the mathematical optimization into the Butler-Volmer equation to derive a relationship of the current-voltage characteristics under a condition that the electrode reaction is in equilibrium.

### Effect of Invention

According to the present invention, it is possible to provide a method of predicting current-voltage characteristics and a prediction device, which enable easy prediction of current-voltage characteristics of a fuel cell including a catalyst composed of any material with high accuracy.

### BRIEF DESCRIPTION OF THE DRAWINGS

FIG. 1 is a flow of steps included in a method of predicting current-voltage characteristics, according to an embodiment of the present invention.

FIG. 2A is a perspective view of a rotating ring-disk electrode of the embodiment.

FIG. 2B is a diagram showing a measurement using the rotating ring-disk electrode of the embodiment.

FIG. 3 is a diagram showing a reaction diffusion model used in the embodiment.

FIG. 4A is a graph showing current-potential curves (LSVs) of a disk electrode obtained in a case where a multi-active site model is applied as Example 1.

FIG. 4B is a graph showing current-potential curves (LSVs) of a ring electrode obtained in a case where a multi-active site model is applied as Example 1.

FIG. 5A is a graph showing LSVs of a disk electrode obtained in a case where a single-active-site model is applied as Comparative Example 1.

FIG. 5B is a graph showing LSVs of a ring electrode obtained in a case where a single-active-site model is applied as Comparative Example 1.

FIG. 6A is a graph showing LSVs of a disk electrode obtained in a case where a multi-active site model is applied as Example 2.

FIG. 6B is a graph showing LSVs of a ring electrode obtained in a case where a multi-active site model is applied as Example 2.

FIG. 7A is a graph showing LSVs of a disk electrode obtained in a case where a single-active-site model is applied as Comparative Example 2.

FIG. 7B is a graph showing LSVs of a ring electrode obtained in a case where a single-active-site model is applied as Comparative Example 2.

FIG. 8A is a graph showing a predicted value and an actual measured value obtained in a case where Example 1 is applied, for current-voltage characteristics of a fuel cell using a carbon alloy catalyst.

FIG. 8B is a graph showing a predicted value and an actual measured value obtained in a case where Example 2 is applied, for current-voltage characteristics of a fuel cell using a platinum-supported catalyst.

FIG. 9A is a graph, showing current-voltage characteristics of a fuel cell including a catalyst layer of Example 3.

FIG. 9B is a graph, showing current-voltage characteristics of a fuel cell including a catalyst layer of Example 4.

FIG. 9C is a graph, showing current-voltage characteristics of a fuel cell including a catalyst layer of Example 5.

FIG. 10A is a graph, showing current-voltage characteristics of a fuel cell including a catalyst layer of Example 6.

FIG. 10B is a graph, showing current-voltage characteristics of a fuel cell including a catalyst layer of Example 3.

FIG. 10C is a graph, showing current-voltage characteristics of a fuel cell including a catalyst layer of Example 7.

### DETAILED DESCRIPTION OF THE INVENTION

Hereinafter, a method of predicting current-voltage characteristics and a current-voltage characteristic prediction device according to embodiments to which the present invention is applied will be described in detail with reference to the drawings. The drawings used in following descriptions may show characteristic portions in an enlarged scale for the sake of convenience to make characteristics easier to understand, and a dimension, a ratio, and the like of each constituent element may not be the same as the actual ones. In addition, materials, dimensions, and the like in following description are examples and can be implemented with appropriate modifications within the scope of the present invention, and the present invention is not limited thereto.

### <Method of Predicting Current-Voltage Characteristics>

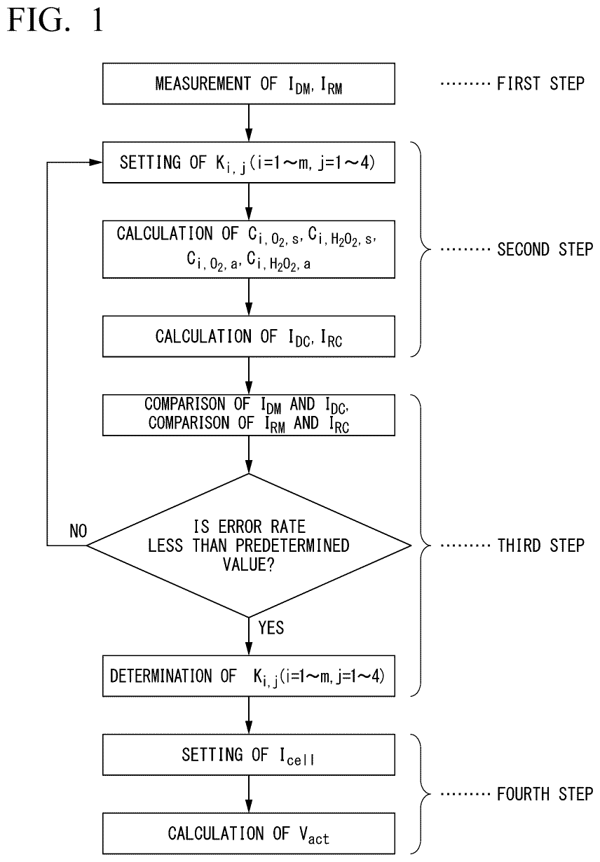

FIG. 1 is a flow of steps included in a method of predicting current-voltage characteristics of a fuel cell, according to an embodiment of the present invention. The method of predicting current-voltage characteristics mainly includes a first step of obtaining the reaction rate constant by mathematical optimization, a second step, a third step, and a fourth step of calculating the activation voltage by using the obtained reaction rate constant and obtaining current-voltage characteristics.

### First Step

A RRDE measurement in which a fuel cell is simulated is performed, and actual measured values of electrode currents (a disk current I_{DM} and a ring current I_{RM}) generated by an electrode reaction are obtained. The actual measured value by the RRDE measurement can be measured at, for example, room temperature, and may be measured at only one temperature, but to consider the influence of temperature, measurement may be performed a plurality of times by changing experimental temperature.

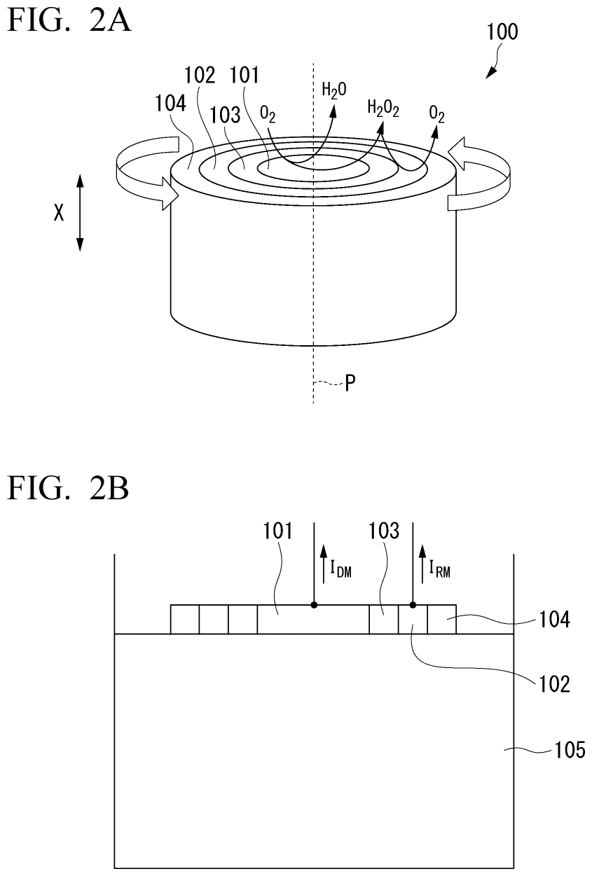

FIG. 2A is a perspective view of a rotating ring-disk electrode 100. The rotating ring-disk electrode 100 mainly includes a columnar disk electrode 101, a cylindrical ring electrode 102, and two insulating films 103 and 104. The disk electrode 101 and the ring electrode 102 are disposed such that center lines P are aligned and spaced apart from each other. The insulating film 103 is disposed to fill a space between an outer side surface of the disk electrode 101 and an inner side surface of the ring electrode 102. The insulating film 104 is disposed to cover an outer side surface of the ring electrode 102.

FIG. 2B is a diagram showing a measurement using the rotating ring-disk electrode 100. The disk electrode 101 and the ring electrode 102 are in contact with an oxygen-saturated solution 105. A power supply (not shown) is connected to each of the disk electrode 101 and the ring electrode 102. Voltages (potentials) of the disk electrode 101 and the ring electrode 102 are controlled while rotating the rotating ring-disk electrode 100 with the center line P as an axis. A catalyst for a fuel cell of an evaluation target can be attached to a surface of the disk electrode 101 or the like.

The oxygen-saturated solution 105 in contact with a surface of each electrode flows outward from a rotation center due to the influence of a centrifugal force caused by rotation. According to this, further oxygen-saturated solution 105 flows into the vicinity of a rotation center. In the disk electrode 101, oxygen is reduced by a catalytic reaction to generate water and hydrogen peroxide, and a disk current I_{DM} flows. In addition, in the ring electrode 102, a part of the hydrogen peroxide generated in the disk electrode 101 is oxidized, and a ring current I_{RM} flows. The disk current I_{DM} and the ring current I_{RM} flowing for each of potentials applied to the disk electrode 101 and the ring electrode 102 are measured to obtain a current-potential curve (LSV).

### Second Step

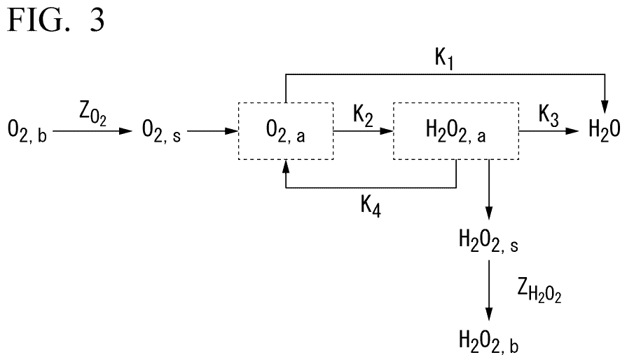

FIG. 3 is a diagram showing a reaction diffusion model used for analysis in the second step. The reaction diffusion model is a model in which a catalyst layer has a finite thickness and a diffusion process occurring at the same time as a reaction in the catalyst layer is introduced. O_{2,b}, O_{2,s}, and O_{2,a} in FIG. 3 represent an oxygen molecule existing at a position (bulk) away from a catalyst layer, an oxygen molecule existing on a surface of the catalyst layer, and an oxygen molecule existing inside the catalyst layer, and H₂O_{2,b}, H₂O_{2,s}, and H₂O_{2,a} represent a hydrogen peroxide molecule existing at a position (bulk) away from the catalyst layer, a hydrogen peroxide molecule existing on the surface of the catalyst layer, and a hydrogen peroxide molecule existing inside the catalyst layer. A reaction diffusion equation reflecting this model is represented by Equation (1) below. O on the right hand side of Equation (1) below represents a zero matrix of 2 rows and 1 column.

$$Equation 6$$

$$\frac{\partial }{\partial t} C = D \frac{{\partial }^{2}}{\partial {x}^{2}} C + KC = O \qquad ( 1 )$$

C in Equation (1) above is a matrix of concentration distributions of an oxygen molecule and a hydrogen peroxide molecule in a catalyst layer, and is represented by Equation (2) below. Both C_{O2} and C_{H2O2}, which are components of C, represent concentration distributions of an oxygen molecule and a hydrogen peroxide molecule in a catalyst layer.

$$Equation 7$$

$$C = ( \begin{matrix}{C}_{{O}_{2}} \\ {C}_{{H}_{2} {O}_{2}}\end{matrix} ) \qquad ( 2 )$$

D in Equation (1) above is a matrix of diffusion coefficients of an oxygen molecule and a hydrogen peroxide molecule, and is represented by Equation (3) below. Both D_{O2} and D_{H2O2}, which are components of D, represent diffusion coefficients of an oxygen molecule and a hydrogen peroxide molecule.

$$Equation 8$$

$$D = ( \begin{matrix}{D}_{{O}_{2}} & 0 \\ 0 & {D}_{{H}_{2} {O}_{2}}\end{matrix} ) \qquad ( 3 )$$

K in Equation (1) above is a matrix of reaction rate constants of a catalyst layer formed on an electrode surface, in consideration of a sequential reaction via hydrogen peroxide, and is represented by Equation (4) below. The sequential reaction via hydrogen peroxide means a series of reactions in which hydrogen peroxide is generated by a reaction between hydrogen ions and oxygen, and water is generated by a reaction between the hydrogen peroxide and the hydrogen ions. Each step of the sequential reaction via hydrogen peroxide is a 2-electron reaction. K₂, K₃, and K₄, which are components of K represents reaction rate constants of the catalyst layer in a synthesis reaction of a hydrogen peroxide molecule, the synthesis reaction of water, and the decomposition reaction of a hydrogen peroxide molecule.

$$Equation 9$$

$$K = ( \begin{matrix}- {K}_{2} & {K}_{4} \\ {K}_{2} & - {K}_{4} - {K}_{3}\end{matrix} ) \qquad ( 4 )$$

In a case where the reaction diffusion equation of Equation (1) is solved on a concentration, a relationship equation with the concentration of a surface of the catalyst layer can be obtained as a general solution. With respect to the general solution, a concentration C_{i,O2,s} and a concentration C_{i,H2O2,s} on a surface of a catalyst layer can be obtained by setting a reaction rate constant K by using a provisional numerical value, and by solving following equation (5) or Equation (9) as a boundary condition according to the concentration of a reactant to be obtained. As a provisional numerical value of each of the reaction rate constants K₂, K₃, and K₄, for example, a value predicted previously, any value generated randomly, or the like can be used.

Here, i in Equation (5) and Equation (9) represents an i-th active site in a case where it is assumed that m active sites with different activities exist in the catalyst layer. In a case where m=1, all active sites in the catalyst layer indicate the activity, and the reaction rate constant K represented by Equation (4) is one kind. In a case where m=2 or more, active sites with different activities exist in the catalyst layer, and m pieces of the reaction rate constants K represented by Equation (4) exist. In the present specification, a case where m=1 is referred to as a single-active-site model, and a case where m=2 or more is referred to as a multi-active-site model. The number m of active sites in a case where the multi-active site model is used is not particularly limited as long as m=2 or more, and for example, m can be set to 2, or may be set to 3 or more. The Equation (1) above is applied to each of m active sites.

Since an actual electrode has a plurality of active sites with different activities due to a difference in microstructure of a catalyst layer, analysis of an electrode reaction can be performed in a situation close to a real environment by using a multi-active-site model. In a case where the multi-active-site model is used, the greater the number of active sites, the more detailed analysis can be performed and the more accurate prediction can be made, and on the other hand, since the computational cost is also increased, the number of active sites can be appropriately set by a computer that is used.

Equation (5) and Equation (9) below are boundary conditions for obtaining concentrations of oxygen and hydrogen peroxide on a catalyst surface, and by applying the boundary conditions to the general solution of Equation (1) above, a concentration C_{i,s} of each component on the catalyst surface and a special solution of Equation (1) are obtained. By applying the obtained special solution of Equation (1) to the right hand side of Equation (13) and Equation (14) below, an average concentration Cia of each component in the catalyst layer is obtained.

C_{i,b}, C_{i,s}, and Cᵢ in Equation (5) and Equation (9) below are a concentration in a bulk, a concentration of a surface of the catalyst layer, and a concentration distribution inside the catalyst layer, in the active site i, and a concentration distribution Cᵢ inside the catalyst layer is a function having a distribution in a thickness direction of the catalyst layer. A concentration C_{i,b} in the bulk may be a saturation concentration in a solution used for an RRDE measurement. In addition, L_{cat} is a thickness of a catalyst layer in the RRDE measurement, and Kᵢ is the reaction rate constant in the active site i. Here, the thickness L_{cat} of the catalyst layer can be obtained by dividing a catalyst amount m_{cat} to be used by a catalyst density ρ_{cat}. Z_{i,O2} and Z_{i,H2O2} can be obtained by Equation (6) and Equation (10). Z⁺_{O2} and d_{c,O2} in Equation (6) below are coefficients obtained by Equation (7) and Equation (8) below, and Z*_{H2O2} and d_{c,H2O2} in Equation (10) are obtained by Equation (11) and Equation (12) below. d_{c} is the thickness of a boundary film depending on a rotation speed of an electrode. dᵢ in Equation (6) and Equation (10) below is the distance between active sites indicating the same activity, and the distance dᵢ between the active sites can be set to any value as an initial value.

D_{O2} in Equation (7) and Equation (8) below is the diffusion coefficient of oxygen, and D_{H2O2} in Equation (11) and Equation (12) below is the diffusion coefficient of hydrogen peroxide. ν in Equation (7) and Equation (11) below represents the viscosity of a bulk, and ω represents the rotation speed of an electrode.

$$[ Equation 10 ]$$

$${Z}_{i , {O}_{2}} ( {C}_{i , {O}_{2} , b} - {C}_{i , {O}_{2} , s} ) = {\int }_{0}^{{L}_{cat}} \{ ( - {K}_{i , 2} \times {C}_{i , {O}_{2}} ) + ( {K}_{i , 4} \times {C}_{i , {H}_{2} {O}_{2}} ) \} dx \qquad ( 5 )$$

$$[ Equation 11 ]$$

$${Z}_{i , {O}_{2}} = {Z}_{{O}_{2}}^{*} \frac{{d}_{i}}{\sqrt{{d}_{c , {O}_{2}^{2}} + {d}_{i}^{2}}} \qquad ( 6 )$$

$$[ Equation 12 ]$$

$${Z}_{{O}_{2}}^{*} = 0.62 \times {D}_{{O}_{2}}^{( 2 / 3 )} \times {ν}^{( - 1 / 6 )} \times {ω}^{( 1 / 2 )} \qquad ( 7 )$$

$$[ Equation 13 ]$$

$${d}_{c , {O}_{2}} = {D}_{{O}_{2}} / {Z}_{{O}_{2}}^{*} \qquad ( 8 )$$

$$[ Equation 14 ]$$

$${Z}_{i , {H}_{2} {O}_{2}} ( {C}_{i , {H}_{2} {O}_{2} , b} - {C}_{i , {H}_{2} {O}_{2} , s} ) = {\int }_{0}^{{L}_{cat}} \{ ( {K}_{i , 2} \times {C}_{i , {O}_{2}} ) - ( {K}_{i , 2} \times {C}_{i , {H}_{2} {O}_{2}} ) - ( {K}_{i , 3} \times {C}_{i , {H}_{2} {O}_{2}} ) \} dx \qquad ( 9 )$$

$$[ Equation 15 ]$$

$${Z}_{i , {H}_{2} {O}_{2}} = {Z}_{{H}_{2} {O}_{2}}^{*} \frac{{d}_{i}}{\sqrt{{d}_{c , {H}_{2} {O}_{2}^{2}} + {d}_{i}^{2}}} \qquad ( 10 )$$

$$[ Equation 16 ]$$

$${Z}_{{H}_{2} {O}_{2}}^{*} = 0.62 \times {D}_{{H}_{2} {O}_{2}}^{( 2 / 3 )} \times {ν}^{( - 1 / 6 )} \times {ω}^{( 1 / 2 )} \qquad ( 11 )$$

$$[ Equation 17 ]$$

$${d}_{c , {H}_{2} {O}_{2}} = {D}_{{H}_{2} {O}_{2}} / {Z}_{{H}_{2} {O}_{2}}^{*} \qquad ( 12 )$$

$$[ Equation 18 ]$$

$${C}_{i , {O}_{2} , a} = \frac{1}{{L}_{cat}} {\int }_{0}^{{L}_{cat}} {C}_{i , {O}_{2}} dx \qquad ( 13 )$$

$$[ Equation 19 ]$$

$${C}_{i , {H}_{2} {O}_{2} , a} = \frac{1}{{L}_{cat}} {\int }_{0}^{{L}_{cat}} {C}_{i , {H}_{2} {O}_{2}} dx \qquad ( 14 )$$

Average concentrations C_{i,O2,a} and C_{i,H2O2,a} inside a catalyst layer, which are obtained by obtaining concentrations C_{i,O2,s} and C_{i,H2O2,s} on a catalyst surface, and reaction rate constants K₂, K₃, and K₄ are substituted into Equation (15) below to obtain a calculated value of a disk current density I_{DC}. In addition, the calculated value of a ring current I_{RC} is obtained by substituting a concentration C_{i,H2O2,s} of hydrogen peroxide on a surface of a catalyst layer into Equation (16) below. The sum of Equation (15) and Equation (16) below is performed for i=1 to m, which is the number of active sites. That is, I_{DC} and I_{RC} are the sum of the electrode current density and the electrode current corresponding to an energy change for each active site. F represents a Faraday constant, N represents a constant determined for each electrode shape, A represents an electrode area, and Z*_{H2O2} represents a constant determined by a viscosity and the diffusion coefficient. Z*_{H2O2} can be obtained by Equation (11) above. K₁ is a reaction rate constant corresponding to a 4-electron reaction in which water is synthesized without the synthesis of hydrogen peroxide, but here, K₁ is set to 0.

$$[ Equation 20 ]$$

$${I}_{DC} = {nFL}_{cat} {{\sum }_{i = 1}}^{m} ( {K}_{i , 2} {C}_{i , {O}_{2} , a} + {K}_{i , 3} {C}_{i , {H}_{2} {O}_{2} , a} - {K}_{i , 4} {C}_{i , {H}_{2} {O}_{2} , a} ) \qquad ( 15 )$$

$$[ Equation 21 ]$$

$${I}_{RC} = nNFA {{\sum }_{i = 1}}^{m} ( {Z}_{{H}_{2} {O}_{2}}^{*} \times {C}_{i , {H}_{2} {O}_{2} , s} ) \qquad ( 16 )$$

### Third Step

Actual measured values of the electrode current density and the electrode current obtained in the first step are compared with calculated values of the electrode current density and the electrode current obtained in the second step, and mathematical optimization (fitting) of calculated values is performed such that a difference between the calculated values and the actual measured values is a specified value or less. Specifically, numerical values of the reaction rate constant K and the distance dᵢ between the active sites are adjusted such that an absolute value |I_{DM}−I_{DC}| of a difference between an actual measured value and a calculated value of the disk current density and an absolute value |I_{RM}−I_{RC}| of a difference between an actual measured value and a calculated value of a ring current are specified values or less. That is, the second step of resetting the reaction rate constant K and the distance dᵢ between active sites to solve a reaction diffusion equation (Equation (1) above) and calculating the disk current density I_{DC} and the ring current I_{RC} is repeated until |I_{DM}−I_{DC}| and |I_{RM}−I_{RC}| are specified values or less.

Mathematical optimization of calculated values can use evolutionary computation, and convergence determination for determining that the evolutionary computation approaches a specific value, and error determination for determining a difference between a calculated value obtained by the evolutionary computation and an actual measured value may be performed.

In a case where the evolutionary computation is used, it is determined that convergence is achieved and a calculated value is obtained in a case where a coefficient of variation of an objective function r represented by Equation (17) below is a predetermined value or less. The coefficient of variation is obtained by dividing a standard deviation of a set of objective function values in each search point in the evolutionary computation by an absolute value of an average value of the objective function values. For example, it can be determined that convergence is achieved in a case where the coefficient of variation is 0.01 or less.

The evolutionary computation is an optimization method that imitates an evolutional process of a biological organism in nature, which is based on Darwin's theory of evolution, and a genetic algorithm or the like can be used. Specifically, first, a set of search points that are candidate solutions is randomly created by a method, such as a Latin hypercube sampling, and an objective function value is calculated. Next, an operation of evolutionary computation such as “mutation/crossover” is performed to create a set of new candidate solutions based on values of a set of search points, and an objective function value is calculated. Then, a “selection” is performed in which corresponding search points and new candidate solutions are compared pair by pair and the one with the smaller objective function value survives while the other is eliminated, and a set of the next search points is determined. In a case where “mutation/crossover” and “selection” are repeated and a coefficient of variation of the objective function r with respect to a set of search points is included in a predetermined range, it is determined that the convergence is achieved, and calculation is terminated.

In Equation (17) below, r is an objective function value, A is an electrode area, and c is a correction coefficient. Here, the correction coefficient c is a value obtained by dividing a ratio of areas under a line to a potential with respect to a current-potential curve (LSV) of a disk electrode and a ring electrode by a capture rate, which represents a proportion of a solution that reaches a ring among solutions moving due to a centrifugal force of rotation from a disk. The capture rate is a constant unique to an electrode, and a value obtained by calculation using a shape factor of the electrode or a value obtained by actual measurement can be used as the capture rate.

E∈E_{obj} of Equation (17) below means that the sum is taken from a potential E belonging to a set E_{obj} (potential condition E_{obj}) of a potential used in an objective function, and can be appropriately set within a potential range measured in the first step. Specifically, a calculation target can be set at equal intervals for a part or all of a potential range measured in the first step, and E_{obj} can be determined. In addition, when an actual measured value obtained by the measurement in the first step is plotted, it is preferable to set a calculation target at a finer interval than a range of a small change in the potential range in which a current value changes greatly, and to set the calculation target as E_{obj}. For example, in a case where the measurement is performed from 0.02 V to 1.2 V in the first step, a total of 20 points may be set for a range of 0.1 V to 1.05 V at intervals of 0.05 V as E_{obj}, or a total of 28 points may be set for a range of 0.1 V to 0.8 V at intervals of 0.05 V, a range of 0.8 V to 0.9 V at intervals of 0.01 V, and 0.9 V to 1.05 V at intervals of 0.05 V.

Error determination, which judges a difference between a calculated value obtained by evolutionary computation and a measured value of RRDE measurement, is achieved when an error index ΔS obtained by Equation (18) below is a predetermined magnitude or less. For example, for an error index ΔS_{D} related to a disk current density and an error index ΔS_{R} related to a ring current, ΔS_{D} may be −1.1 or less and ΔS_{R} may be −0.90 or less, and it is preferable that ΔS_{D} is −1.2 or less and ΔS_{R} is −1.0 or less, it is more preferable that ΔS_{D} is −1.3 or less and ΔS_{R} is −1.1 or less, and it is even more preferable that both ΔS_{D} and ΔS_{R} are −1.3 or less. Within the above-described range, it can be determined that a calculated value determined to be converged by Equation (17) below is optimized with a small error from an actual measured value, and current-voltage characteristics of a fuel cell can be predicted with high accuracy.

E∈E_met In Equation (18) means that, for each potential E belonging to a set E met of potentials (potential condition E met) used in an error index, the sum of corresponding values at those potentials is taken, and can be appropriately set within a potential range measured in the first step. Specifically, points obtained by dividing a range of 0.1 to 1.05 V at equal intervals can be set as Eₘₑₜ, and for example, total 20 points may be set for a range of 0.1 V to 1.05 V at intervals of 0.05 V. Since there is a possibility that an error cannot be correctly evaluated when the number of potentials used for calculation of an error index is small, it is preferable that the potential range measured in the first step is divided into 20 points or more at equal intervals. Since the number of potentials used for calculation of an error index does not affect evaluation of an error even when the number is great, the number is not particularly limited.

A potential condition E_{obj} of an objective function and a potential condition Eₘₑₜ of an error index may be the same as or different from each other.

$$[ Equation 22 ]$$

$${log}_{10} ( A {\sum }_{E ∈ {E}_{obj}} \vert {I}_{DM} - {I}_{DC} \vert ) + {log}_{10} ( c {\sum }_{E ∈ {E}_{obj}} \vert {I}_{RM} - {I}_{RC} \vert ) \qquad ( 17 )$$

$$[ Equation 23 ]$$

$$Δ S = {log}_{10} \frac{{\sum }_{E ∈ {F}_{met}} \vert {I}_{M} - {I}_{C} \vert}{{\sum }_{E ∈ {F}_{met}} \vert {I}_{M} \vert} \qquad ( 18 )$$

### Fourth Step

Each of calculated values of reaction rate constants K_{i,2}, K_{i,3}, and K_{i,4} for each active site after mathematical optimization is substituted into a Butler-Volmer equation, and an activation voltage V_{act} under the condition that an electrode reaction is in equilibrium is obtained. Since the method does not require information regarding the type of catalyst, the method can be applied to any catalyst. By plotting the obtained activation voltage with respect to a current, a calculated IV curve indicating current-voltage characteristics can be obtained.

In the present specification, in the Butler-Volmer equation described above, a relationship between a current density value and the reaction rate constant obtained by each reaction can be represented by Equation (19) to Equation (21) below. In addition, the relationship between the cell current density value under the condition that the electrode reaction is in equilibrium and the current density value obtained by each reaction can be described as Equation (24).

I_{i,2}, I_{i,3}, and I_{i,4} in Equation (19) to Equation (21) below are exchange current densities, K_{i,2}, K_{i,3}, and K_{i,4} are reaction rate constants after mathematical optimization, C_{i,O2,fc} and C_{i,H2O2,fc} are concentrations of oxygen and hydrogen peroxide, n is the number of reaction electrons, a is an electrochemical mobility, R is a gas constant, T is a cell temperature, E⁰ is a redox potential, and E is an electrode potential. In addition, i is an integer of 1 to m representing an active site. Here, C_{i,O2,fc} and C_{i,H2O2,fc} are calculated by Equation (22) and Equation (23) below. P_{O2} in Equation (22) and Equation (23) below is a partial pressure of oxygen, and can be calculated from the supply amount of oxygen and a back pressure of a fuel cell.

In Equation (19) to Equation (21) below, m_{cat} represents the catalyst amount in an electrode, and ρ_{cat} represents a catalyst density. Here, ρ_{cat} is a value obtained from an element ratio, a pore volume, and a void ratio of a catalyst, and a platinum-supported catalyst has a greater value than a carbon alloy catalyst. A ratio of m_{cat} to ρ_{cat} is a value proportional to a thickness of a catalyst layer, and a rate constant depending on the catalyst amount can be calculated by multiplying the ratio by the reaction rate constant K.

I_{cell} in Equation (24) below is a cell current density, I_{i,2}, I_{i,3}, and I_{i,4} are exchange current densities at an active site i calculated by Equation (19) to Equation (21) above, and I_{xH2} is a hydrogen cross-leak current density. The sum of the equation (24) is performed on m pieces of active sites with different activities. Here, as a cross-leak current density of hydrogen, a value obtained by a method of calculating from a hydrogen permeability of an electrolyte membrane, a method of performing an actual measurement by using an MEA, or the like can be used.

$$[ Equation 24 ]$$

$${I}_{i , 2} = nF \frac{{m}_{cat}}{{ρ}_{cat}} {K}_{i , 2} {C}_{i , {H}_{2} {O}_{2} , fc} exp \{ \frac{nF {α}_{i , 2}}{RT} ( {E}_{2}^{0} - E ) \} \qquad ( 19 )$$

$$[ Equation 25 ]$$

$${I}_{i , 3} = nF \frac{{m}_{cat}}{{ρ}_{cat}} {K}_{i , 3} {C}_{i , {H}_{2} {O}_{2} , fc} exp \{ \frac{nF {α}_{i , 3}}{RT} ( {E}_{3}^{0} - E ) \} \qquad ( 20 )$$

$$[ Equation 26 ]$$

$${I}_{i , 4} = nF \frac{{m}_{cat}}{{ρ}_{cat}} {K}_{i , 4} {C}_{i , {H}_{2} {O}_{2} , fc} exp \{ \frac{nF {α}_{i , 4}}{RT} ( {E}_{4}^{0} - E ) \} \qquad ( 21 )$$

$$[ Equation 27 ]$$

$${C}_{i , {O}_{2} , fc} = \frac{{P}_{{O}_{2}}}{RT} \times \frac{{K}_{i , 3} + {K}_{i , 4}}{{K}_{i , 2} + {K}_{i , 3} + {K}_{i , 4}} \qquad ( 22 )$$

$$[ Equation 28 ]$$

$${C}_{i , {H}_{2} {O}_{2} , fc} = \frac{{P}_{{O}_{2}}}{RT} \times \frac{{K}_{i , 2}}{{K}_{i , 2} + {K}_{i , 3} + {K}_{i , 4}} \qquad ( 23 )$$

$$[ Equation 29 ]$$

$${I}_{cell} - {{\sum }^{m}}_{i = 1} ( {I}_{i , 2} + {I}_{i , 3} - {I}_{i , 4} ) + {I}_{{xH}_{2}} = 0 \qquad ( 24 )$$

A cell voltage is preferably obtained by subtracting a decrease due to a concentration overvoltage η_{con} from an activation voltage of a fuel cell. The concentration overvoltage is an energy loss that occurs due to a shortage of a reactant in an electrode reaction, depends on transport characteristics of the reactant, and greatly changes depending on an electrode material, a cell structure, and the like. In addition, influence of the concentration overvoltage is greater in a high current region. The concentration overvoltage η_{con} can be obtained by, for example, Equation (25). I_{cell} and I_{d1} respectively denote a cell current density and a limiting diffusion current density. α^{c} is a numerical value known as a transfer coefficient of cathode concentration overvoltage, and a numerical value range is 0 to 1. For specific numerical values, for example, a document (G. Inoue et al., Journal of Power Sources, 154 (2006), 18-34, DOI: 10.1016/j.jpowsour.2005.03.216.) can be referred to.

$$[ Equation 30 ]$$

$${η}_{con} = \frac{RT}{{α}^{c} F} ln ( 1 - \frac{{I}_{cell}}{{I}_{dl}} ) \qquad ( 25 )$$

A cell voltage is preferably obtained by subtracting a decrease due to a resistance overvoltage ηₒₕₘ from an activation voltage of a fuel cell. The resistance overvoltage is an energy loss required for movement of electric charges itself inside a fuel cell, and influence thereof is large in the middle between a low current region and a high current region. The resistance overvoltage ηₒₕₘ can be obtained by, for example, Equation (26) to Equation (29) below. Equation (29) is Bruggeman's equation.

In Equation (26) below, t^{cat} is a thickness of a catalyst layer of MEA, and σ is conductivity. In Equation (26) below, f=e⁻ represents that a catalyst is used as a filler, and f=H⁺ represents that an ionomer is used as a filler.

In Equation (27) below, σₑ₋, σₑ₋, i, σₑ₋, s, Tᵢ, and T are conductivity of electrons, a constant of a term that does not depend on a temperature related to electron conduction, a constant of a term that depends on a temperature related to electron conduction, a reference temperature, and a cell temperature. In Equation (28) below, O_{H+}, O_{H+}, s, O_{H+}, i, and λ are conductivity of protons, a constant of a term that depends on humidity related to proton conduction, a constant of a term that does not depend on the humidity related to the proton conduction, and water activity which is a variable depending on humidity. In Equation (29) below, V_{f} and σ_{f} are a volume of a filler and conductivity of the filler, and σₘ is conductivity of a matrix.

$$[ Equation 31 ]$$

$${η}_{ohm} = {I}_{cell} ( \frac{{t}^{cat}}{{σ}_{p} {\vert}_{f = {e}^{-} , m = {H}^{+}}} - \frac{{t}^{cat}}{{σ}_{p} {\vert}_{f = {H}^{+} , m = {e}^{-}}} ) \qquad ( 26 )$$

$$[ Equation 32 ]$$

$${σ}_{{e}^{-}} = \frac{1}{{σ}_{{e}^{-} , i} \{ 1 + {σ}_{{e}^{-} , s} ( {T}_{i} - T ) \}} \qquad ( 27 )$$

$$[ Equation 33 ]$$

$${σ}_{H +} = exp \{ 1280 ( \frac{1}{303} - \frac{1}{T} ) \} ( {σ}_{H + , s} λ + {σ}_{H + , i} ) \qquad ( 28 )$$

$$[ Equation 34 ]$$

$${σ}_{{p}^{=}} \frac{- ( 3 {V}_{f} - 2 ) {σ}_{m} + ( 3 {V}_{f} - 1 ) {σ}_{f} + {[ {\{ - ( 3 {V}_{f} - 2 ) {σ}_{m} + ( 3 {V}_{f} - 1 ) {σ}_{f} \}}^{2} + 8 {σ}_{f} {σ}_{m} ]}^{1 / 2}}{4} \qquad ( 29 )$$

In relation to a concentration overvoltage, a first database may be generated for a relationship between a catalyst amount and a concentration overvoltage, and prediction may be performed with reference to the first database. In addition, in relation to a resistance overvoltage, a second database may be generated for a relationship between a ratio (I/C ratio) of an ionomer amount to a catalyst amount in a catalyst layer and the resistance overvoltage, and prediction may be performed with reference to the second database.

### <Current-Voltage Characteristic Prediction Device>

A current-voltage characteristic prediction device used for a method of predicting current-voltage characteristics described above mainly includes an input device, a first calculation device, a second calculation device, and a third calculation device. The input device has a function of inputting actual measured values of the electrode current density of a disk electrode and the electrode current of a ring electrode, which are generated by an electrode reaction, through an RRDE measurement. The first calculation device has a function of solving Equation (1) above to obtain calculated values of the electrode current density and the electrode current from the obtained concentration distribution. The second calculation device has a function of performing mathematical optimization of the calculated values such that a difference between the actual measured value and the calculated value is a specified value or less. The third calculation device has a function of deriving a relationship of current-voltage characteristics under the condition that an electrode reaction is in equilibrium by substituting the calculated value after the mathematical optimization into a Butler-Volmer equation.

As described above, in the method of predicting current-voltage characteristics according to the present embodiment, the current-voltage characteristics of a fuel cell are obtained by using a current calculated from the reaction rate constant in which a sequential reaction is considered and a molecular concentration in which a three-dimensional diffusion is considered. In the calculation of current, information on a material of a catalyst is not required, and special work or equipment is not required. Therefore, in the method of predicting current-voltage characteristics according to the present embodiment, the current-voltage characteristics of a fuel cell including a catalyst composed of any material can be easily predicted with high accuracy.

In addition, in the method of predicting current-voltage characteristics according to the present embodiment, a theoretical analytical formula exists, and thus, it is possible to easily detect an optimum condition for maximizing an output of the fuel cell with high accuracy by adjusting various parameters.

### EXAMPLES

Hereinafter, effects of the present invention will be described in greater detail with reference to Examples. The present invention is not limited to following

Examples, and can be appropriately modified and implemented within the scope not departing from the gist thereof.

Various measurement methods and a configuration of a fuel cell used in the present example are shown.

### [RRDE Measurement]

In a measurement (RRDE measurement) performed in the first step of the above-described embodiment by using a rotating ring-disk electrode, evaluation is performed by using a rotating ring-disk electrode device (RRDE-3A rotating ring-disk electrode device ver. 1.2, manufactured by BAS Inc.) and a dual electrochemical analyzer (CHI700C, manufactured by ALS Co., Ltd.).

In a working electrode of the electrode device, the working electrode supporting a catalyst was prepared by adjusting a catalyst for a fuel cell cathode and 5% Nafion (registered trademark) (Nafion perfluorinated ion exchange resin, 5% dispersion liquid (product number: 510211), manufactured by Sigma-Aldrich) into a slurry shape, and coating a working electrode (an RRDE-3A ring-disk electrode, a platinum ring-gold disk electrode, disk diameter 4 mm, manufactured by BAS Co., Ltd.) with the catalyst and Nafion such that a content per unit area of an electrode of a catalyst was 0.1 mg/cm², and then drying the working electrode.

A platinum electrode (Pt counter electrode 23 cm, manufactured by BAS Inc.) was used as a counter electrode, and a reversible hydrogen electrode (RHE) (an accumulation type reversible hydrogen electrode, manufactured by ECF Co., Ltd.) was used as a reference electrode. In addition, a 0.1 M perchloric acid aqueous solution was used as an electrolyte.

Linear sweep voltammetry was performed in a nitrogen atmosphere and an oxygen atmosphere by using a rotating ring-disk electrode device of a three-electrode type having a working electrode including the above-described catalyst, a platinum electrode as a counter electrode, and a reversible hydrogen electrode (RHE) as a reference electrode.

First, nitrogen bubbling was performed with respect to an electrolyte for 10 minutes to remove oxygen from the electrolyte. Thereafter, the electrode was rotated at a rotation speed of 1600 rpm, and a current density when potential sweep was performed at a sweep speed of 20 mV/sec was recorded as a current-potential curve (LSV) which is a function of a potential.

Subsequently, oxygen bubbling was performed for 10 minutes to fill the inside of the electrolyte with saturated oxygen. Thereafter, the electrode was rotated at a rotation speed of 1600 rpm, and a current density when potential sweep was performed at a sweep speed of 20 mV/sec was recorded as a current-potential curve (LSV) which is a function of a potential.

An actual measured value of the current-potential curve (LSV) of an oxygen reduction reaction was obtained by subtracting the LSV in an oxygen atmosphere from the LSV in a nitrogen atmosphere. In the obtained LSV of the oxygen reduction reaction, signs were given to the numerical values such that a reduction current had a negative value and an oxidation current had a positive value.

### [IV Measurement (Actual Measured Value)]

An IV measurement was performed to obtain an actual measured value of current-voltage characteristics of a fuel cell.

First, in order to make a battery electrode, each electrode catalyst and 5% Nafion (registered trademark) (Nafion, a perfluorinated ion exchange resin, 5% dispersion liquid (product number: 510211), manufactured by Sigma-Aldrich Co., LLC) were adjusted to have a slurry shape, applied onto a gas diffusion layer (“29BC”, manufactured by SGL Carbon SE) in a range of an area of 5 cm², and dried, and thereby, a catalyst layer is formed on the gas diffusion layer. As a catalyst for anode, a platinum-supported catalyst (UNPC40-II, manufactured by Ishifuku Metal Industry Co., Ltd.) was used.

A solid polymer electrolyte membrane (“NAFION (registered trademark) 211” manufactured by DuPont company) was disposed between a battery electrode including a catalyst for a cathode made as described above and a battery electrode including the catalyst for an anode, and was pressure-bonded, and thereby, an MEA was made. A pair of gaskets was attached to the MEA, and the MEA was further sandwiched between a pair of separators, and thereby a single cell of a fuel cell was made.

A power generation test was performed on the single cell of the fuel cell produced as described above by using a fuel cell automatic evaluation system (manufactured by TOYO Corporation) and actual measured values of current-voltage characteristics were obtained.

In the power generation test, an oxidizing gas (air) having a relative humidity of 100% RH was supplied to a positive electrode side of single cell of the fuel cell heated to 70° C. at a back pressure of 70 kPa in units of 2.5 L/min, fuel gas (hydrogen) having a relative humidity of 100% RH was supplied to the negative electrode side in units of 1.0 L/min, the open circuit voltage was measured for 5 minutes, and then the cell voltage was measured by holding the cell current density at each current density for 3 minutes from 4.0 A/cm² to 0 A/cm².

### [Configuration of Fuel Cell (Predicted Value)]

Materials of each configuration of a fuel cell required for prediction of current-voltage characteristics are set as follows. Items not listed below are configured in the manner as the measurement of an actual measured value above.
Electrolyte membrane: solid polymer electrolyte membrane (“Nafion (registered trademark) 211” manufactured by DuPont company)
Catalyst layer: carbon (catalyst)+5% Nafion (registered trademark) (ionomer)
Gas diffusion layer: (“29BC”, manufactured by SGL Carbon company)

### Example 1

In a fuel cell in which a carbon alloy catalyst is used as a catalyst, current-voltage characteristics in a case where a multi-active-site model is applied were predicted as follows.

In the first step of the above-described embodiment, the RRDE measurement was performed by using a carbon alloy catalyst as a catalyst used for a working electrode, and an actual measured value of LSV was obtained. The carbon alloy catalyst was made by the method described in PCT International Publication No. WO2017/209244. Conditions were set to a catalyst amount m_{cat}: 0.1 mg/cm², a catalyst density Peat: 2.2 g/cm³, and an I/C ratio: 0.4, and a rotating ring-disk electrode with a capture rate of 0.424 was used.

In the second step of the above-described embodiment, initial values of the reaction rate constant and the distance between active sites in each catalyst layer, in a synthesis reaction of hydrogen peroxide molecules, a synthesis reaction of water molecules, and a decomposition reaction of hydrogen peroxide molecules, were set as any values, and a calculated value of LSV was obtained by solving a reaction diffusion equation represented by Equation (1). Here, it was assumed that the number of active sites was 2 (in Equation (15) and Equation (16), m=2, and the sum is taken for i=1 to 2). A diffusion coefficient D_{O2} of oxygen was set to 2×10⁻⁵ (cm²/sec), and a diffusion coefficient D_{H2O2} of hydrogen peroxide was set to 1.43×10⁻⁵ (cm²/sec) for calculation.

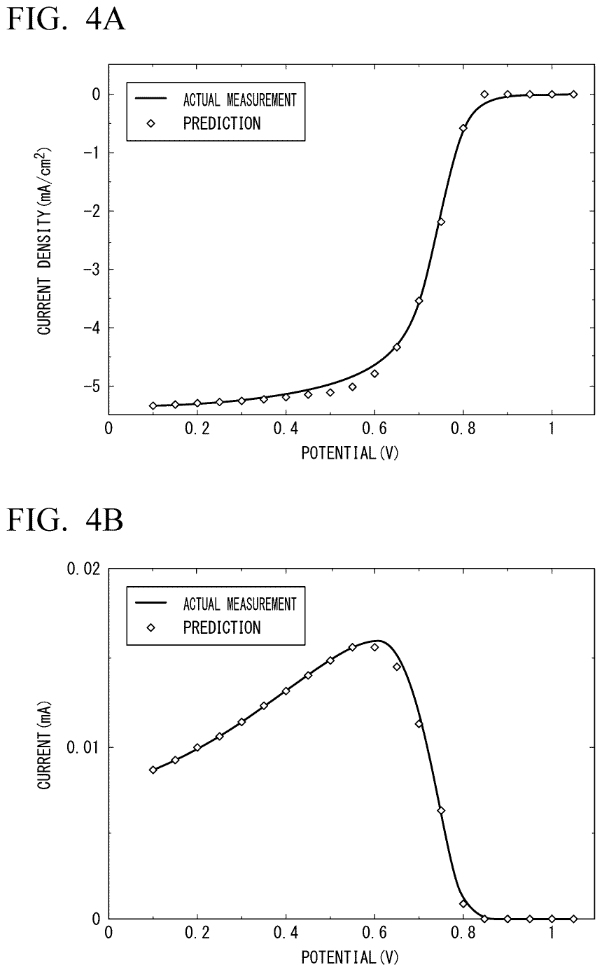

In the third step of the above-described embodiment, by using the actual measured value obtained in the first step and the calculated value obtained in the second step, mathematical optimization using evolutionary computation was performed such that a coefficient of variation of an objective function r in Equation (17) was 0.01 or less, and the reaction rate constant in each catalyst layer, in a synthesis reaction of hydrogen peroxide molecules, a synthesis reaction of water molecules, and a decomposition reaction of hydrogen peroxide molecules, was obtained. The value of an error index ΔS represented by Equation (18) above was −1.80 in a disk electrode and −1.56 in a ring electrode. The range in which the sum of Equation (17) and Equation (18) above was taken was set to 20 points obtained by dividing a range of 0.1 to 1.05 V at intervals of 0.05 V. FIGS. 4A and 4B are graphs showing LSVs of a disk electrode and a ring electrode after mathematical optimization.

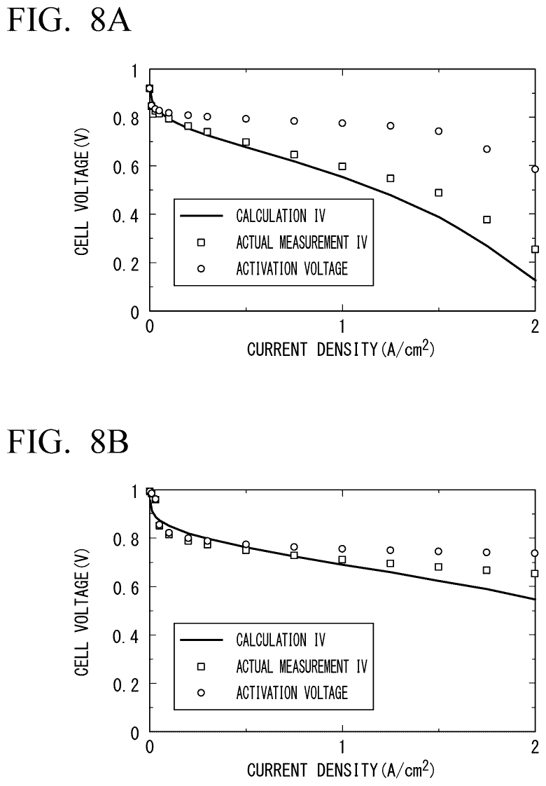

In the fourth step of the above-described embodiment, current-voltage characteristics were predicted by solving a Butler-Volmer equation in an equilibrium state by using the calculated value of the reaction rate constant obtained in the third step. Furthermore, based on a configuration of the fuel cell, a concentration overvoltage and a resistance overvoltage were calculated, and subtraction is performed, thereby, more detailed current-voltage characteristics were obtained. FIG. 8 (a) is a graph showing a predicted value and an actual measured value obtained in a case where Example 1 is applied, for current-voltage characteristics of a fuel cell using a carbon alloy catalyst.

### Comparative Example 1

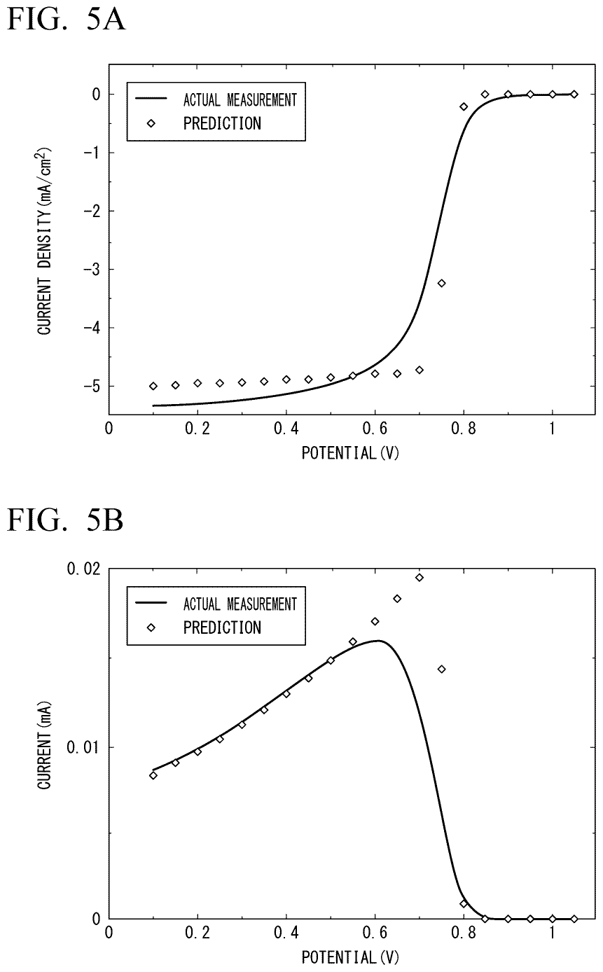

In the manner as Example 1, an RRDE measurement in the first step of the above-described embodiment was performed, and a logical LSV was obtained from a reaction diffusion equation represented by Equation (1) above by using a single-active-site model in which the number of active sites in the second step was set to one, and mathematical optimization of the third step was performed. The value of the error index ΔS was −1.08 in a disk electrode and −0.90 in a ring electrode. FIGS. 5A and 5B are graphs showing LSVs of a disk electrode and a ring electrode after mathematical optimization.

By comparing the graphs of FIGS. 4 and 5, it can be seen that, when a carbon alloy catalyst is used for a working electrode, LSVs of a disk electrode and a ring electrode can be fitted with higher accuracy in a case where a multi-active-site model is applied than in a case where a single-active-site model is applied. This is also clear from a value of an error index ΔS.

### Example 2

Example 2 was executed in the manner as Example 1, except that a commercially available platinum-supported catalyst (Pt/C) (platinum supported amount: 50 wt %, catalytic support: carbon black) for a fuel cell cathode was used as a catalyst used for a working electrode. Conditions were set to a catalyst amount m_{cat}: 0.1 mg/cm², a catalyst density ρ_{cat}: 11.8 g/cm³, and an I/C ratio: 0.4. The value of an error index ΔS in the third step of the above-described embodiment was −1.36 in a disk electrode and −1.39 in a ring electrode.

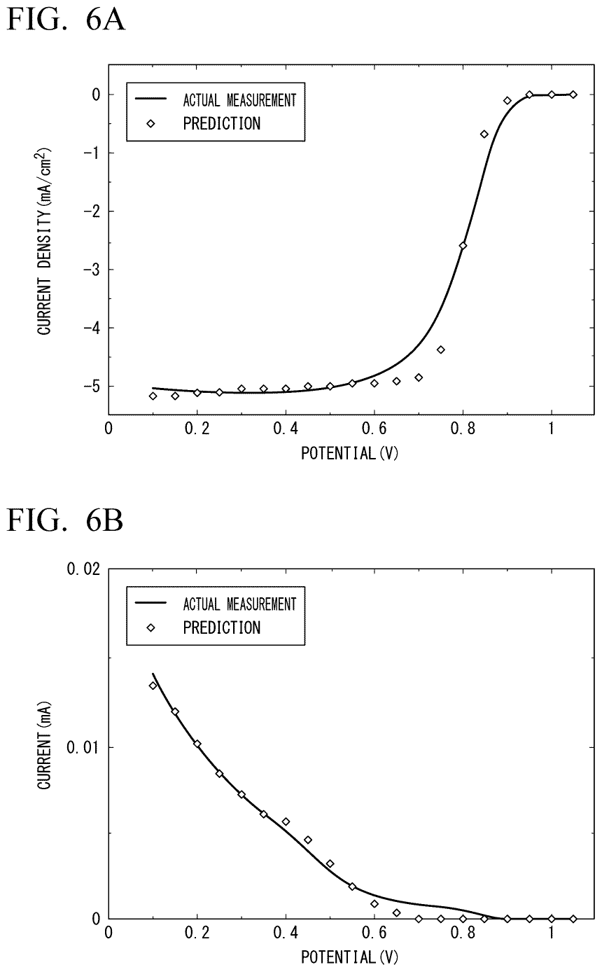

FIGS. 6A and 6B are graphs showing LSVs of a disk electrode and a ring electrode after mathematical optimization. In addition, FIG. 8B is a graph showing a predicted value and an actual measured value obtained in a case where Example 2 is applied, for current-voltage characteristics of a fuel cell using a platinum-supported catalyst (Pt/C).

### Comparative Example 2

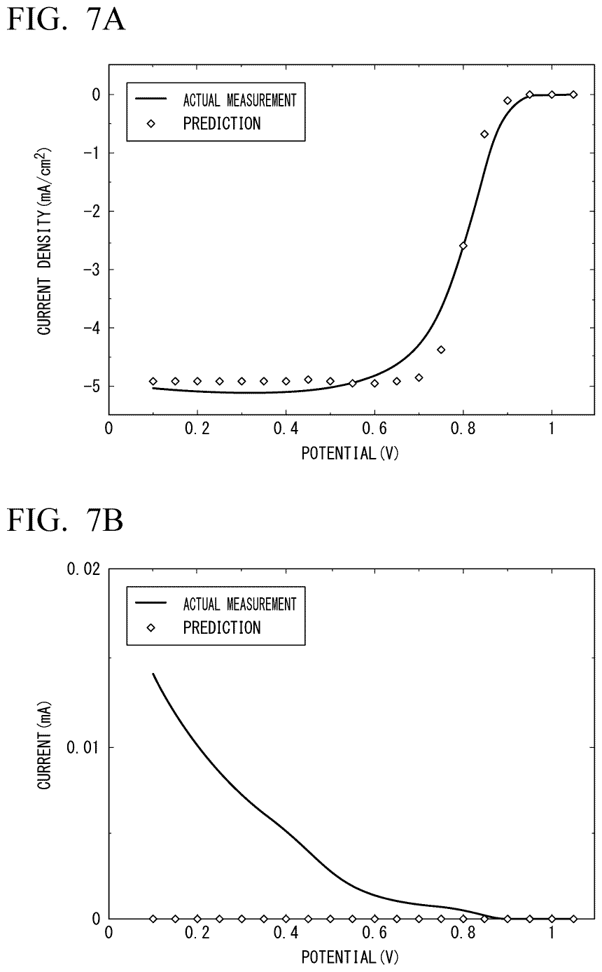

Comparative Example 2 was executed in the manner as Comparative Example 1, except that a commercially available platinum-supported catalyst (Pt/C) for a fuel cell cathode was used as the catalyst used for a working electrode as in Example 2. The value of an error index ΔS in the third step of the above-described embodiment was −1.78 in a disk electrode and −0.03 in a ring electrode. FIGS. 7A) and 7B are graphs showing LSVs of a disk electrode and a ring electrode after mathematical optimization.

By comparing FIGS. 6A, 6B and 7A, 7B, it can be seen that, when the platinum-supported catalyst (Pt/C) is used, the LSVs of the disk electrode and the ring electrode can be fitted with higher accuracy in a case where the multi-active-site model is applied than in a case where the single-active-site model is applied. This is also clear from a value of an error index ΔS. In a case where the single-active-site model is used, since the LSV of the ring electrode after mathematical optimization is greatly deviated from an actual measured value, the third step cannot be completed, and the fourth step cannot be performed, and thus, current-voltage characteristics of a fuel cell using the platinum-supported catalyst (Pt/C) cannot be predicted.

From FIGS. 8A and 8B, it can be seen that in both a case where a carbon alloy catalyst is used as a catalyst and a case where a platinum-supported catalyst (Pt/C) is used as the catalyst, a curve obtained by prediction overlaps a distribution of plots of actual measured values, and a favorable prediction of current-voltage characteristics can be performed. From the result, it can be seen that, in a method of predicting current-voltage characteristics using a multi-active-site model, current-voltage characteristics of a fuel cell including a catalyst composed of any material can be predicted with high accuracy.

In addition, it can be seen that an activation voltage in a low current region is in good agreement with an activation voltage obtained from a Butler-Volmer equation. Therefore, it is possible to evaluate the performance of a catalyst for a cathode used in a fuel cell from current-voltage characteristics in a low current region. In addition, in a high voltage region, a decrease due to a resistance overvoltage also increases, and thus, catalytic performance can be evaluated for all current regions by subtracting a resistance overvoltage or a concentration overvoltage from an activation voltage.

### Example 3

The actual measurement and prediction of current-voltage characteristics were performed for a fuel cell including a catalyst layer in which the catalyst amount m_{cat} was set to 1.5 mg/cm² and the I/C ratio was set to 0.7. Materials of each configuration of a fuel cell were set in the manner as Example 1.

### Example 4

An actual measurement and prediction of current-voltage characteristics were performed for a fuel cell including a catalyst layer in which the catalyst amount m_{cat} was set to 2.5 mg/cm² and the I/C ratio was set to 0.7. Materials of each configuration of a fuel cell were set in the manner as Example 1.

### Example 5

The actual measurement and prediction of current-voltage characteristics were performed for a fuel cell including a catalyst layer in which the catalyst amount m_{cat} was set to 3.5 mg/cm² and the I/C ratio was set to 0.7. Materials of each configuration of a fuel cell were set in the manner as Example 1.

### Example 6

The actual measurement and prediction of current-voltage characteristics were performed for a fuel cell including a catalyst layer in which the catalyst amount m_{cat} was set to 1.5 mg/cm² and the I/C ratio was set to 1.1. Materials of each configuration of a fuel cell were set in the manner as Example 1.

### Example 7

The actual measurement and prediction of current-voltage characteristics were performed for a fuel cell including a catalyst layer in which the catalyst amount m_{cat} was set to 1.5 mg/cm² and the I/C ratio was set to 0.3. Materials of each configuration of a fuel cell were set in the manner as Example 1.

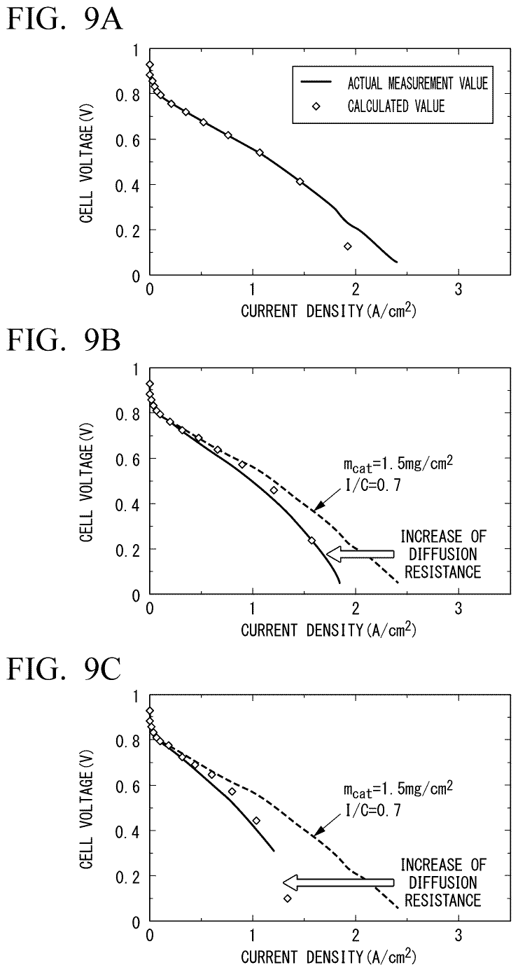

FIGS. 9A, 9B, and 9C are graphs showing actual measurement results and prediction results of current-voltage characteristics of Example 3, Example 4, and Example 5. Each of horizontal axes of the graphs indicates a current density (A/cm²), and each of vertical axes of the graphs indicates a voltage (V). In any of the graphs, predicted curves substantially overlap actual measurement curves, and thus, it can be seen that current-voltage characteristics obtained by an actual measurement can be predicted with high accuracy by a method of predicting current-voltage characteristics. In addition, by comparing the three graphs, it can be seen that, when the catalyst amount m_{cat} is a value close to 1.5, an output is almost a maximum value, and as the catalyst amount m_{cat} is greater than 1.5, the output is less than the maximum value. It is considered that this result is due to an increase in diffusion resistance in a fuel cell as the amount m_{cat} of a catalyst increases to be more than 1.5.

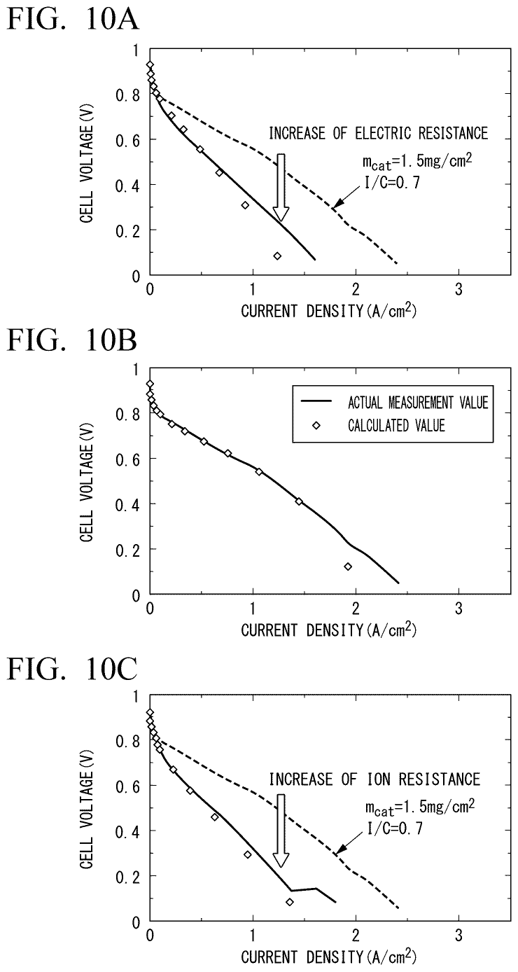

FIGS. 10A, 10B, and 10C are graphs showing actual measurement results and the prediction results of current-voltage characteristics of Example 6, Example 3, and Example 7. Horizontal axes and vertical axes of the graphs are the same as the horizontal axes and vertical axes of the graphs in FIGS. 9A, 9B, and 9C. In any of the graphs, predicted curves substantially overlap actual measurement curves, and thus, it can be seen that current-voltage characteristics obtained by an actual measurement can be predicted with high accuracy by a method of predicting current-voltage characteristics. In addition, by comparing the three graphs, it can be seen that, when the I/C ratio is a value close to 0.7, an output is almost a maximum value, and as the I/C ratio is a value farther from 0.7, the output is less than the maximum value. It is considered that this result is due to the fact that, when the I/C ratio is set to be greater than 0.7, electric resistance in a fuel cell increases, and when the I/C ratio is set to be less than 0.7, ion resistance in the fuel cell increases.

It can be seen that, in both a case in which platinum is used as a catalyst and a case where a carbon alloy is used as the catalyst, curves obtained by prediction overlap a distribution of plots of actual measured values, and favorable prediction of current-voltage characteristics can be performed. From the results, it can be seen that, in a method of predicting current-voltage characteristics, the current-voltage characteristics of a fuel cell including a catalyst composed of any material can be predicted with high accuracy.

### EXPLANATION OF REFERENCES

100 rotating ring-disk electrode
101 disk electrode
102 ring electrode
103,104 insulating film
105 oxygen-saturated solution
P center line
I_{D} disk current
I_{R} ring current

1. A method of predicting current-voltage characteristics of a fuel cell, the method comprising:
a first step of performing an RRDE measurement that simulates the fuel cell to obtain actual measured values of an electrode current density of a disk electrode and an electrode current of a ring electrode which are generated by an electrode reaction;
a second step of solving Equation (1) below regarding a concentration distribution of oxygen molecules and hydrogen peroxide molecules on an electrode surface in the RRDE measurement to obtain a calculated value of the electrode current density and the electrode current from the obtained concentration distribution;
a third step of performing mathematical optimization of the calculated value such that a difference between the actual measured values and the calculated value is equal to or less than a specified value; and
a fourth step of substituting the calculated value after the mathematical optimization into a Butler-Volmer equation to obtain an activation voltage under a condition that the electrode reaction is in equilibrium, and obtaining the current-voltage characteristics,
wherein the calculated value obtained in the second step is a sum of the electrode current density and the electrode current, which correspond to an energy change for each active site,
$$Equation 1$$
$$\frac{\partial }{\partial t} C = D \frac{{\partial }^{2}}{\partial {x}^{2}} C + KC = O \qquad ( 1 )$$
(C represents a concentration distribution of the oxygen molecules and the hydrogen peroxide molecules in a catalyst layer, D represents a diffusion coefficient of the oxygen molecules and the hydrogen peroxide molecules, and K represents a reaction rate constant of the catalyst layer formed on the electrode surface).

2. The method of predicting current-voltage characteristics according to claim 1,
wherein the concentration distribution C, the diffusion coefficient D, and the reaction rate constant K are each represented by Equation (2) to Equation (4) below,
$$Equation 2$$
$$C = ( \begin{matrix}{C}_{{O}_{2}} \\ {C}_{{H}_{2} {O}_{2}}\end{matrix} ) \qquad ( 2 )$$
$$Equation 3$$
$$D = ( \begin{matrix}{D}_{{O}_{2}} & 0 \\ 0 & {D}_{{H}_{2} {O}_{2}}\end{matrix} ) \qquad ( 3 )$$
$$Equation 4$$
$$K = ( \begin{matrix}- {K}_{2} & {K}_{4} \\ {K}_{2} & - {K}_{4} - {K}_{3}\end{matrix} ) \qquad ( 4 )$$
(C_{O2} and C_{H2O2} represent concentration distributions of the oxygen molecules and the hydrogen peroxide molecules in the catalyst layer, D_{O2} and D_{H2O2} represent diffusion coefficients of oxygen molecules and hydrogen peroxide molecules, and K₂, K₃, and K₄ represent reaction rate constants of the catalyst layer in a synthesis reaction of the hydrogen peroxide molecules, a synthesis reaction of water molecules, and a decomposition reaction of the hydrogen peroxide molecules).

3. The method of predicting the current-voltage characteristics according to claim 1,
wherein the energy change for each active site is an energy change for two or more active sites with different activities in the catalyst layer.

4. The method of predicting the current-voltage characteristics according to claim 1,
wherein, in the fourth step, the Butler-Volmer equation is multiplied by a ratio of a catalyst amount to a catalyst density.

5. The method of predicting current-voltage characteristics according to claim 1,
wherein the mathematical optimization in the third step is performed such that an error index ΔS represented by Equation (5) below is in a range of −1.1 or less at the disk electrode and −0.9 or less at the ring electrode,
$$Equation 5$$
$$Δ S = {log}_{10} \frac{{\sum }_{E ∈ {F}_{met}} \vert {I}_{M} - {I}_{C} \vert}{{\sum }_{E ∈ {F}_{met}} \vert {I}_{M} \vert} \qquad ( 5 )$$
(I_{M} and I_{C} are the actual measured value and the calculated value of the electrode current density of the disk electrode and the electrode current of the ring electrode in the RRDE measurement, and a sum is performed with respect to a potential condition Eₘₑₜ in an actually measured potential).

6. The method of predicting current-voltage characteristics according to claim 1,
wherein, in the fourth step, a decrease due to a concentration overvoltage and a resistance overvoltage is subtracted from the activation voltage of the fuel cell.

7. The method of predicting current-voltage characteristics according to claim 6,
wherein a first database is generated for a relationship between a catalyst amount and the concentration overvoltage, and
the concentration overvoltage is predicted with reference to the first database.

8. The method of predicting current-voltage characteristics according to claim 6,
wherein a second database is generated for a relationship between a ratio of an ionomer amount to a catalyst amount in the catalyst layer and the resistance overvoltage, and
the resistance overvoltage is predicted with reference to the second database.

9. A current-voltage characteristic prediction device that is used for the method of predicting current-voltage characteristics according to claim 1, the current-voltage characteristic prediction device comprising:
an input device configured to input the actual measured values of the disk-electrode current density and the electrode current of the ring-electrode generated by the electrode reaction, by using the RRDE measurement;
a first calculation device configured to solve the Equation (1) to obtain the calculated value of the electrode current density and the electrode current from the obtained concentration distribution;
a second calculation device configured to perform the mathematical optimization of the calculated value such that a difference between the actual measured values and the calculated value is a specified value or less; and
a third calculation device configured to substitute the calculated values after the mathematical optimization into the Butler-Volmer equation to derive a relationship of the current-voltage characteristics under a condition that the electrode reaction is in equilibrium.
